(19) United States
(12) Patent Application Publication
(10) Pub. No.: US 2024/0154390 A1
(43) Pub. Date: May 9, 2024

(54) SEMICONDUCTOR OPTICAL ELEMENT

(71) Applicant: Mitsubishi Electric Corporation, Tokyo (JP)

(72) Inventors: Takaya MORIKAWA, Tokyo (JP); Kosuke SHINOHARA, Tokyo (JP)

(73) Assignee: Mitsubishi Electric Corporation, Tokyo (JP)

(21) Appl. No.: 18/574,646

(22) PCT Filed: Jul. 9, 2021
(86) PCT No.: PCT/JP2021/025986

§ 371 Date: Dec. 27, 2023

(51) Int. Cl. H01S 5/223; H01S 5/227; H01S 5/32; H01S 5/343

(52) U.S. Cl. CPC H01S 5/2231; H01S 5/2275; H01S 5/3211; H01S 5/34353

(57) ABSTRACT

A semiconductor optical element of the present disclosure includes: a ridge structure provided on a first-conductivity-type semiconductor substrate and including a first-conductivity-type cladding layer and an active layer; a buried structure provided on both side surfaces of the ridge structure; a second-conductivity-type cladding layer and a second-conductivity-type contact layer provided on a surface of the buried structure; a second-conductivity-type ridge upper cladding layer provided above the ridge structure; a recess having a bottom surface formed of an upper surface of the second-conductivity-type ridge upper cladding layer and side surfaces formed of the second-conductivity-type cladding layer and the second-conductivity-type contact layer; a mesa structure having both side surfaces formed by a mesa extending from the second-conductivity-type contact layer to the first-conductivity-type semiconductor substrate.

### TECHNICAL FIELD

The present disclosure relates to a semiconductor optical element.

### BACKGROUND ART

In recent years, an amount of data communications in mobile communication systems has been rapidly increasing. In order to process enormous amounts of data communications at high speed, even faster operation is desired for semiconductor optical elements, represented by a semiconductor laser, which is a light source.

Patent Document 1 discloses an optical semiconductor device in which a buried region covering both side surfaces of an active layer is formed. The optical semiconductor device described in Patent Document 1 has a mesa structure in which the buried region made of, for example, an iron-doped AlInAs (Aluminum Indium Arsenide) semiconductor is provided on both side surfaces of a ridge structure having the active layer and cladding layers provided on upper and lower surfaces of the active layer. In such device structure, current injected into the active layer can be confined by the buried region, and in addition, the optical confinement to the active layer in the lateral direction can be increased.

### CITATION LIST

### Patent Document

Patent Document 1: Japanese Laid-Open Patent Publication No. 2005-286032

### SUMMARY OF THE INVENTION

### Problem to be Solved by the Invention

When a semiconductor optical element is used as a light source for optical communication by high-speed modulation, a relaxation oscillation frequency of the semiconductor optical element needs to be higher than a cutoff frequency of a light-receiving side low-pass filter. The relaxation oscillation frequency fᵣ generally has a proportional relationship represented by the following equation (1).

$$[ Equation 1 ]$$

$${f}_{r} ∝ \sqrt{\frac{Γ}{L \cdot W \cdot d \cdot q} \cdot \frac{dg}{dN} \cdot {η}_{i} \cdot ( {I}_{op} - {I}_{th} )} \qquad ( 1 )$$

In Equation (1), Γ represents an optical confinement factor, L represents a cavity length, W represents an active layer width, d represents an active layer thickness, q represents an elementary charge, dg/dN represents a differential gain, ηᵢ represents an internal quantum efficiency, Iₒₚ represents an operating current, and Iₜₕ represents a threshold current. As can be seen from the equation (1), the larger the optical confinement factor Γ, the higher the relaxation oscillation frequency fᵣ.

In the device structure of the optical semiconductor device described in Patent Document 1, the buried region formed on both sides of the ridge structure increase the light confinement to the active layer in the lateral direction, resulting in a higher relaxation oscillation frequency fᵣ. However, the optical confinement to the active layer in the longitudinal direction is not sufficiently large. When the relaxation oscillation frequency fᵣ is lower than the cutoff frequency of the light-receiving side low-pass filter due to insufficient optical confinement to the active layer of the semiconductor optical element, the low-pass filter cannot completely cut off the relaxation oscillation, resulting in degradation of transmission characteristics.

The present disclosure has been made to solve the above-described problems, and an object of the present disclosure is to provide a semiconductor optical element capable of performing high-speed modulation by further increasing the relaxation oscillation frequency by increasing optical confinement to an active layer in the longitudinal direction.

### Means to Solve the Problem

A semiconductor optical element according to the present application includes: a first-conductivity-type semiconductor substrate; a stripe-shaped ridge structure provided on the first-conductivity-type semiconductor substrate and including a first-conductivity-type cladding layer and an active layer; a buried structure buried so as to cover both side surfaces of the ridge structure; a second-conductivity-type ridge upper cladding layer provided above the ridge structure; a second-conductivity-type cladding layer and a second-conductivity-type contact layer provided on a surface of the buried structure; a stripe-shaped recess provided in the second-conductivity-type cladding layer and the second-conductivity-type contact layer, the stripe-shaped recess having a bottom surface formed of an upper surface of the second-conductivity-type ridge upper cladding layer and side surfaces formed of the second-conductivity-type cladding layer and the second-conductivity-type contact layer; a stripe-shaped mesa structure including the ridge structure and having both side surfaces formed by a mesa extending from the second-conductivity-type contact layer to the first-conductivity-type semiconductor substrate; and an insulating film covering the bottom surface and the side surfaces of the recess, a surface of the second-conductivity-type contact layer, and the both side surfaces of the mesa structure.

### Effect of the Invention

According to the semiconductor optical element disclosed in the present application, since the layer thickness of the ridge upper cladding layer provided above the active layer can be made thinner than that of the cladding layer provided other than above the active layer by the recess provided in the mesa structure, the optical confinement to the active layer in the longitudinal direction becomes large and thus the relaxation oscillation frequency becomes high, therefore, a semiconductor optical element capable of high-speed modulation is obtained.

### BRIEF DESCRIPTION OF THE DRAWINGS

FIG. 1 is a schematic view of a semiconductor optical element according to Embodiment 1.

FIG. 2 is a cross-sectional view in a direction perpendicular to a cavity in the semiconductor optical element according to Embodiment 1.

FIG. 3 shows the dependence of the optical confinement factor on the layer thickness of the ridge upper cladding layer in the semiconductor optical element according to Embodiment 1.

FIG. 4 is a cross-sectional view in the direction perpendicular to the cavity in a semiconductor optical element according to Modification 1 of Embodiment 1.

FIG. 5 is a cross-sectional view in the direction perpendicular to the cavity in a semiconductor optical element according to Modification 2 of Embodiment 1.

FIG. 6 is a cross-sectional view in the direction perpendicular to the cavity in a semiconductor optical element according to Modification 3 of Embodiment 1.

FIG. 7 is a cross-sectional view in the direction perpendicular to the cavity in a semiconductor optical element according to Embodiment 2.

FIG. 8 is a cross-sectional view in the direction perpendicular to the cavity in a semiconductor optical element according to Embodiment 3.

FIG. 9 is a schematic view of a semiconductor optical element according to Embodiment 4.

FIG. 10 is a cross-sectional view of the ridge structure including the recess in the direction parallel to the cavity direction in the semiconductor optical element according to Embodiment 4.

### DESCRIPTION OF EMBODIMENTS

### Embodiment 1

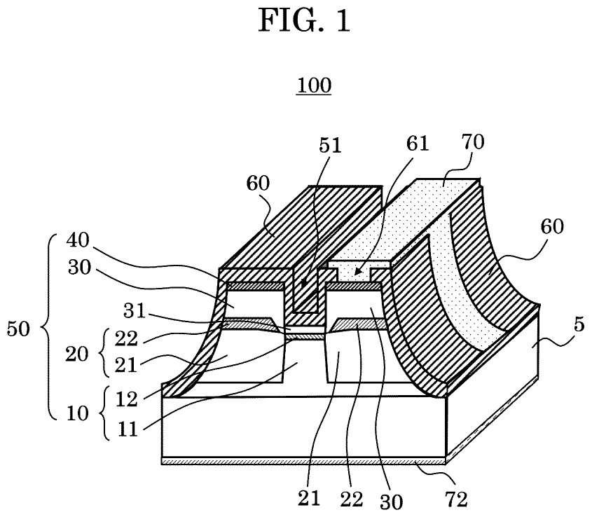

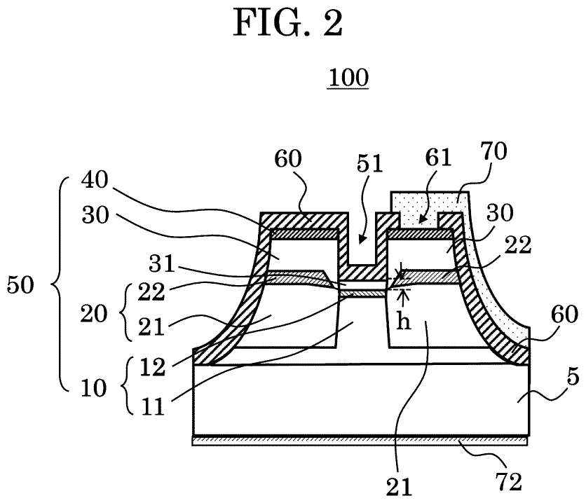

FIG. 1 is a schematic view of a semiconductor optical element 100 according to Embodiment 1, and FIG. 2 is a cross-sectional view in a direction perpendicular to a cavity in the semiconductor optical element 100.

The semiconductor optical element 100 according to Embodiment 1 including: a stripe-shaped ridge structure 10 including an n-type InP cladding layer 11 (a first-conductivity-type cladding layer) and an active layer 12, which are sequentially laminated on an n-type InP substrate 5 (a first-conductivity-type semiconductor substrate); a buried structure 20 including a p-type InP first buried layer 21 (a second-conductivity-type first buried layer) and an n-type InP second buried layer 22 (a first-conductivity-type second buried layer), which are buried so as to cover both side surfaces of the stripe-shaped ridge structure 10; a p-type InP ridge upper cladding layer 31 (a second-conductivity-type ridge upper cladding layer) provided above the ridge structure 10; a p-type InP cladding layer 30 (a second-conductivity-type cladding layer) and a p-type InGaAsP (Indium Gallium Arsenide Phosphide) contact layer 40 (a second-conductivity-type contact layer) provided above the buried structure 20; a stripe-shaped recess 51 provided in the p-type InP cladding layer 30 and the p-type InGaAsP contact layer 40, the stripe-shaped recess 51 having a bottom surface formed of an upper surface of the p-type InP ridge upper cladding layer 31 and side surfaces formed of the p-type InP cladding layer 30 and the p-type InGaAsP contact layer 40; a stripe-shaped mesa structure 50 including the ridge structure 10 and having both side surfaces formed by a mesa extending from the p-type InGaAsP contact layer 40 to the n-type InP substrate 5; an insulating film 60 covering the bottom surface and the side surfaces of the recess 51, a surface of the p-type InGaAsP contact layer 40, and the both side surfaces of the mesa structure 50; a stripe-shaped insulating film opening 61 provided in the insulating film 60 on the p-type InGaAsP contact layer 40; a p-side electrode 70 (a second-conductivity-type-side electrode) in contact with the p-type InGaAsP contact layer 40 through the insulating film opening 61; and an n-side electrode 72 (a first-conductivity-type-side electrode) provided on a rear surface of the n-type InP substrate 5.

In the semiconductor optical element 100 according to Embodiment 1, the buried structure 20 increases the optical confinement to the active layer 12 in the lateral direction, that is, the direction parallel to the surface of the n-type InP substrate 5, and the recess 51 increases the optical confinement to the active layer 12 in the longitudinal direction, that is, the direction perpendicular to the surface of the n-type InP substrate 5, thus providing an effect that the relaxation oscillation frequency of the semiconductor optical element 100 is increased.

In the semiconductor optical element 100 according to Embodiment 1, the p-side electrode 70 is provided on the upper surface of the stripe-shaped mesa structure 50 so as to be in contact with the p-type InGaAsP contact layer 40 through the insulating film opening 61 formed along the lateral direction of the recess 51, so that the distance between the active layer 12 and the p-type InGaAsP contact layer 40 can be set to be long, thus providing an effect that the loss caused by absorption of the laser light emitted from the active layer 12 by the p-type InGaAsP contact layer 40 is suppressed.

An example of a method for manufacturing the semiconductor optical element 100 according to Embodiment 1 will be described below.

First, the n-type InP cladding layer 11 having a carrier-concentration of 4.0×10¹⁸ cm⁻³ and a layer thickness of 0.5 μm and the active layer 12 having a layer thickness of 0.2 μm and made of an aluminum-gallium-indium-arsenide (AlGaInAs) based or an InGaAsP based semiconductor material are sequentially crystal-grown on a main surface consisting of a (001) crystal plane of the n-type InP substrate 5 doped with silicon (Si) and having a carrier-concentration of 4.0×10¹⁸ cm⁻³ by a crystal growth method such as an metal-organic chemical vapor deposition (MOCVD) or a molecular beam epitaxy (MBE) (first crystal growth step).

Note that the constituent material of the n-type InP cladding layer 11 is not limited to InP, but may be an InP based semiconductor material.

In the element structure described above, the active layer 12 may include a multiple quantum well structure. Optical confinement layers made of the AlGaInAs based or the InGaAsP based semiconductor material having a refractive index larger than that of the n-type InP cladding layer 11 may be provided on the upper and lower surfaces of the active layer 12. In the above description, an example of InP based semiconductor materials are given, but GaAs (Gallium Arsenide) based semiconductor materials, GaN (Gallium Nitride) based semiconductor materials, or the like may be used.

After the growth of the above layers, an insulating material such as SiO₂ is deposited on the surface of the active layer 12. Examples of a method for forming the SiO₂ film include a vacuum vapor deposition method, a chemical vapor deposition (CVD) method, and a sputtering method. After forming the SiO₂ film, the SiO₂ film is patterned into a stripe-shaped SiO₂ film having a desired width and extending in the cavity direction by photolithography and etching techniques. The stripe-shaped SiO₂ film functions as an etching mask for forming the ridge structure 10. The etching mask is not limited to the SiO₂ film, but may be a silicon nitride (SiN) film.

Using the etching mask made of the SiO₂ film, the ridge structure 10 with a width of 1.2 μm is formed by etching to a depth that reaches the n-type InP substrate 5 or the n-type InP cladding layer 11 (ridge structure forming step). As the etching method, dry etching is preferable, but wet etching may be used.

After the ridge structure 10 is formed, the p-type InP first buried layer 21 doped with Zn and having a carrier concentration of 5.0×10¹⁷ cm⁻³, and the n-type InP second buried layer 22 doped with Si and having a carrier concentration of 6.0×10¹⁸ cm⁻³ are sequentially crystal-grown by MOCVD or the like so as to cover the both side surfaces of the ridge structure 10, thereby forming the buried structure 20 (second crystal growth step).

The constituent material of the p-type InP first buried layer 21 is not limited to InP, but may be any InP based semiconductor material. The same applies to the n-type InP second buried layer 22.

Each buried layer of the buried structure 20 may be made of a semi-insulating material such as InP doped with Ru (ruthenium) or Fe (iron). Further, the structure of the buried structure 20 is not limited to the above-described two-layer structure, but may be a semiconductor layer having different carrier concentration or conductivity, or a laminate obtained by combining a plurality of such semiconductor layers. After the crystal growth of the buried structure 20, the stripe-shaped SiO₂ film is removed by dry etching or the like.

Next, the p-type InP cladding layer 30 doped with Zn and having a concentration of 1.0×10¹⁸ cm⁻³ and a layer thickness of 2.0 μm, and the p-type InGaAsP contact layer 40 doped with Zn and having a concentration of 1.6×10¹⁹ cm⁻³ and a layer thickness of 0.3 μm are sequentially crystal-grown on the upper surface of the ridge structure 10 and the surface of the buried structure 20 by MOCVD or the like (third crystal growth step).

Note that the constituent material of the p-type InP cladding layer 30 is not limited to InP, but may be any InP based semiconductor material. The constituent material of the p-type InGaAsP contact layer 40 is not limited to InGaAsP, but may be any InGaAsP based semiconductor material.

The carrier concentration of the p-type InGaAsP contact layer 40 is set to 1.6×10¹⁹ cm⁻³ in the above-described example, but it is not limited to such a numerical value but may be any value as long as it is higher than the carrier concentration of the p-type InP cladding layer 30.

Next, a stripe-shaped resist pattern extending in the cavity direction is formed on the surface of the p-type InGaAsP contact layer 40 by photolithography and etching techniques. Using an etching mask composed of the resist pattern, etching is performed to a depth reaching the n-type InP substrate 5 or the n-type InP cladding layer 11 to form the mesa structure 50 having a width of 10 μm and including the ridge structure 10 therein (mesa structure forming step). As the etching method, wet etching is preferable, but dry etching may be used.

After the mesa structure 50 is formed, a stripe-shaped resist pattern extending in the cavity direction is formed on the upper surface of the mesa structure 50 at a position corresponding to the upper portion of the ridge structure 10 by photolithography and etching techniques. The portion corresponding to the upper portion of the ridge structure 10 is etched using an etching mask composed of the resist pattern. That is, the entire p-type InGaAsP contact layer 40 and a part of the p-type InP cladding layer 30 in the opening of the etching mask are removed by etching to form the recess 51 having a width of 1.2 μm (recess forming step).

A portion remaining on the upper surface of the ridge structure 10 in the p-type InP cladding layer 30 resulting from the formation of the recess 51 functions as the p-type InP ridge upper cladding layer 31. The layer thickness of the p-type InP ridge upper cladding layer 31 is controlled within a range of 0.3 to 0.4 μm by etching described above.

After the recess 51 is formed, an insulating film 60 made of an insulating material such as SiO₂ and having a thickness of 0.4 μm is formed so as to cover the bottom surface and the side surfaces of the recess 51, the surface of the p-type InGaAsP contact layer 40, and the both side surfaces of the mesa structure 50. Examples of a method for forming the insulating film 60 include the vacuum deposition method, the CVD method, and the sputtering method.

After the formation of the insulating film 60, a stripe-shaped resist pattern extending in the cavity direction is formed on the insulating film 60 by photolithography and etching techniques, and then the insulating film 60 is etched so as to expose the surface of the p-type InGaAsP contact layer 40, thereby forming the insulating film opening 61.

Next, the p-side electrode 70 is formed so as to be in contact with the p-type InGaAsP contact layer 40 through the insulating film opening 61 by using a film formation technique such as a vacuum deposition method or a sputtering method. Further, the n-side electrode 72 is formed on the rear surface of the n-type InP substrate 5 by a similar film forming method (electrode forming step).

Each of the n-side electrode 72 and the p-side electrode 70 is made of a metallic element such as gold (Au), platinum (Pt), zinc (Zn), germanium (Ge), nickel (Ni), titanium (Ti), or a combination of two or more of these metals.

The semiconductor optical element 100 includes a front end surface and a rear end surface formed by cleavage in the optical axis direction of laser light, and thus the cavity having a length of 200 μm is formed.

Through the steps described above, the semiconductor optical element 100 according to Embodiment 1 is manufactured.

In the above description, the numerical values of the doping concentration, the layer thickness, the width, and the like of each semiconductor layer are typical examples, and are not limited to the numerical values or ranges shown in the examples.

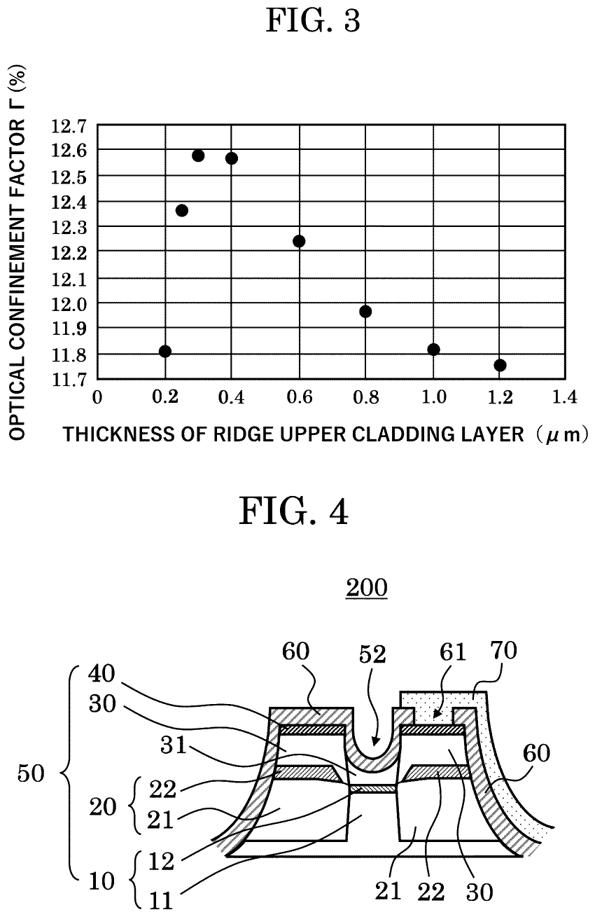

FIG. 3 shows a result of a simulation performed by a beam propagation method (BPM) on a change in the optical confinement factor Γ when the layer thickness h of the p-type InP ridge upper cladding layer 31 shown in the cross-sectional view of FIG. 2 is changed in the semiconductor optical element 100 according to Embodiment 1. In the simulation, the refractive index of the active layer 12 is assumed to be 3.42, and the refractive indices of the n-type InP cladding layer 11, the p-type InP cladding layer 30, and the p-type InP ridge upper cladding layer 31 are assumed to be 3.21.

When the layer thickness of the p-type InP ridge upper cladding layer 31 is 0.3 μm or more, the optical confinement factor Γ decreases as the layer thickness h of the p-type InP ridge upper cladding layer 31 increases, and the optical confinement factor Γ increases as the layer thickness h decreases.

However, when the layer thickness of the p-type InP ridge upper cladding layer 31 is less than 0.3 μm, the optical confinement factor Γ rapidly decreases as the layer thickness h of the p-type InP ridge upper cladding layer 31 decreases.

From the above simulation results, it is preferable that the layer thickness h of the p-type InP ridge upper cladding layer 31 is set within the range of 0.3 to 0.4 μm. The optical confinement factor Γ may be further increased by adjusting not only the layer thickness h of the p-type InP ridge upper cladding layer 31 but also the layer thickness of the n-type InP cladding layer 11 or the layer thicknesses of the optical confinement layers formed on the upper and lower surfaces of the active layer 12.

As described above, according to the semiconductor optical element of Embodiment 1, since the layer thickness of the ridge upper cladding layer provided above the active layer can be made thinner than that of the cladding layer provided other than above the active layer by the recess provided in the mesa structure, the optical confinement to the active layer in the longitudinal direction is increased and the relaxation oscillation frequency is increased, thus providing an effect of obtaining a semiconductor optical element that enables high-speed modulation.

### Modification 1 of Embodiment 1

FIG. 4 is a cross-sectional view in a direction perpendicular to a cavity in a semiconductor optical element 200 according to Modification 1 of Embodiment 1. In FIG. 4, the n-type InP substrate 5 is omitted. In FIG. 2 showing the cross-sectional view of the semiconductor optical element 100 according to Embodiment 1, the cross-section of the recess 51 in the direction perpendicular to the optical axis direction has a rectangular shape with an opening at the top. In contrast, in the semiconductor optical element 200 according to Modification 1 of Embodiment 1, a bottom surface of the recess 52 has a curved surface. In other words, a cross section of the recess 52 in a direction perpendicular to the optical axis direction has a U-shape.

The recess 52 is formed by, for example, wet etching using a Br based chemical solution such as hydrogen bromide (HBr) as an etchant.

In the semiconductor optical element 200 according to Modification 1 of Embodiment 1, similarly to the semiconductor optical element 100 according to Embodiment 1, by providing the recess 52, the optical confinement to the active layer 12 in the longitudinal direction is increased, and the relaxation oscillation frequency is increased, thus providing an effect of obtaining a semiconductor optical element that enables high-speed modulation.

In the semiconductor optical element 200 according to Modification 1 of Embodiment 1, since the distance between the n-type InP second buried layer 22 and the recess 52 is further increased, the element resistance of the semiconductor optical element 200 is reduced, thus providing an effect of reducing the operating current.

### Modification 2 of Embodiment 1

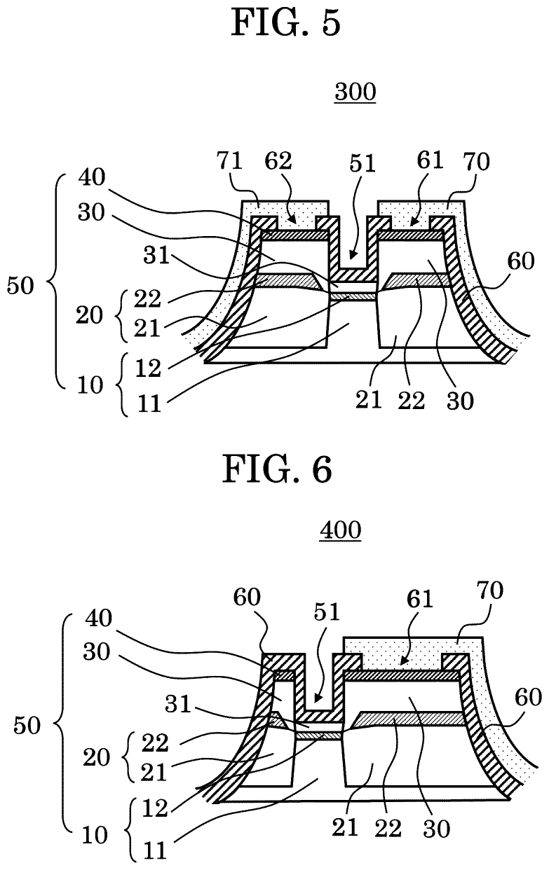

FIG. 5 is a cross-sectional view in a direction perpendicular to a cavity in a semiconductor optical element 300 according to Modification 2 of Embodiment 1. In FIG. 5, the n-type InP substrate 5 is omitted. In FIG. 2 showing a cross-sectional view of the semiconductor optical element 100 according to Embodiment 1, the insulating film opening 61 is formed only in one region of the upper surface of the mesa structure 50 divided by the recess 51.

In contrast, in the semiconductor optical element 300 according to Modification 2 of Embodiment 1, an insulating film opening 62 is also provided in the other region of the upper surface of the mesa structure 50, and a p-side electrode 71 is formed so as to be in contact with the surface of the p-type InGaAsP contact layer 40 through the insulating film opening 62.

That is, on the upper surface of the mesa structure 50, the insulating film opening 61 and the insulating film opening 62 are provided at positions opposed to each other across the recess 51, and the p-side electrode 70 and the p-side electrode 71 are provided in the respective openings so as to be in contact with the surface of the p-type InGaAsP contact layer 40. Note that the recess 51 may be formed to have the U-shape by the wet etching using the Br based chemical solution or the like.

In the semiconductor optical element 300 according to Modification 2 of Embodiment 1, similarly to the semiconductor optical element 100 according to Embodiment 1, by providing the recess 51, the optical confinement to the active layer 12 in the longitudinal direction is increased and the relaxation oscillation frequency is increased, thus providing an effect of obtaining a semiconductor optical element that enables high-speed modulation.

Further, in the semiconductor optical element 300 according to Modification 2 of Embodiment 1, current can be equally injected from the two p-side electrodes 70 and 71 into the active layer 12, thus providing an effect that heat generation of the semiconductor optical element can be suppressed and power consumption can be suppressed.

### Modification 3 of Embodiment 1

FIG. 6 is a cross-sectional view in a direction perpendicular to a cavity in a semiconductor optical element 400 according to Modification 3 of Embodiment 1. In FIG. 6, the n-type InP substrate 5 is omitted. In FIG. 2 showing a cross-sectional view of the semiconductor optical element 100 according to Embodiment 1, the ridge structure 10 and the recess 51 are provided at the center of the mesa structure 50. In contrast, in the semiconductor optical element 400 according to Modification 3 of Embodiment 1, the ridge structure 10 and the recess 51 are provided at positions shifted from the center of the mesa structure 50 in a direction perpendicular to the cavity direction.

In other words, the central axes of the ridge structure 10 and the recess 51 are separated by a predetermined distance within the mesa structure 50 from the central axis of the mesa structure 50 in the direction perpendicular to the surface of the n-type InP substrate 5. Note that the recess 51 may be formed in the U-shape by the wet etching using the Br based chemical solution or the like.

In the semiconductor optical element 400 according to Modification 3 of Embodiment 1, similarly to the semiconductor optical element 100 according to Embodiment 1, by providing the recess 51, the optical confinement to the active layer 12 in the longitudinal direction is increased and the relaxation oscillation frequency is increased, thus providing an effect of obtaining a semiconductor optical element that enables high-speed modulation.

In the semiconductor optical element 400 according to Modification 3 of Embodiment 1, since the central axes of the ridge structure 10 and the recess 51 are separated by the predetermined distance within the mesa structure 50 from the central axis of the mesa structure 50, the area of one side of the upper surface of the mesa structure 50 is increased and the opening width of the insulating film opening 61 can also be widened, so that the contact area between the p-type InGaAsP contact layer 40 and the p-side electrode 70 can also be increased and as a result, the contact resistance therebetween is reduced, thus providing an effect of reducing the element resistance of the semiconductor optical element and thus reducing the operating current.

### Embodiment 2

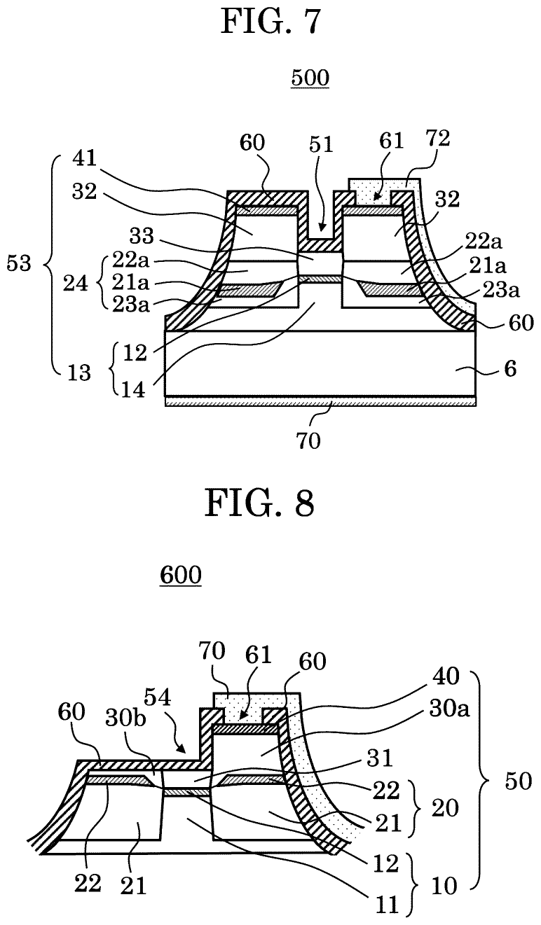

FIG. 7 is a cross-sectional view in a direction perpendicular to a cavity in a semiconductor optical element 500.

The semiconductor optical element 500 according to Embodiment 2 including: a stripe-shaped ridge structure 13 including a p-type InP cladding layer 14 (a first-conductivity-type cladding layer) and an active layer 12, which are sequentially laminated on a p-type InP substrate 6 (a first-conductivity-type semiconductor substrate); a buried structure 24 including a p-type InP first buried layer 23a (a first-conductivity-type first buried layer), an n-type InP second buried layer 21a (a second-conductivity-type second buried layer), and a p-type InP third buried layer 22a (a first-conductivity-type third buried layer), which are buried so as to cover both side surfaces of the stripe-shaped ridge structure 13; an n-type InP ridge upper cladding layer 33 (a second-conductivity-type ridge upper cladding layer) provided above the ridge structure 13 and having a layer thickness in a range of 0.3 to 0.4 μm; an n-type InP cladding layer 32 (a second-conductivity-type cladding layer) and an n-type InGaAsP contact layer 41 (a second-conductivity-type contact layer) provided above the buried structure 24; a stripe-shaped recess 51 provided in the n-type InP cladding layer 32 and the n-type InGaAsP contact layer 41, the stripe-shaped recess 51 having a bottom surface formed of an upper surface of the n-type InP ridge upper cladding layer 33 and side surfaces formed of the n-type InP cladding layer 32 and the n-type InGaAsP contact layer 41; a stripe-shaped mesa structure 53 including the ridge structure 13 and having both side surfaces formed by a mesa extending from the n-type InGaAsP contact layer 41 to the p-type InP substrate 6; an insulating film 60 covering the bottom surface and the side surfaces of the recess 51, a surface of the n-type InGaAsP contact layer 41, and the both side surfaces of the mesa structure 53; a stripe-shaped insulating film opening 61 provided in the insulating film 60 on the n-type InGaAsP contact layer 41; an n-side electrode 72 (a second-conductivity-type-side electrode) in contact with the n-type InGaAsP contact layer 41 through the insulating film opening 61; and a p-side electrode 70 (a first-conductivity-type-side electrode) provided on a rear surface of the p-type InP substrate 6.

In the semiconductor optical element 500 according to Embodiment 2, as in the semiconductor optical element 100 according to Embodiment 1, the buried structure 24 increases the optical confinement to the active layer 12 in the lateral direction, that is, the direction parallel to the surface of the p-type InP substrate 6, and the recess 51 increases the optical confinement to the active layer 12 in the longitudinal direction, that is, the direction perpendicular to the surface of the p-type InP substrate 6, thus providing an effect that the relaxation oscillation frequency of the semiconductor optical element 500 is increased.

In the semiconductor optical element 500 according to Embodiment 2, the distance between the active layer 12 and the n-type InGaAsP contact layer 41 can be set to be long by providing the n-side electrode 72 through the insulating film opening 61 formed on the upper surface of the stripe-shaped mesa structure 53 along the lateral direction of the recess 51, thus providing an effect that the loss caused by the absorption of laser light by the n-type InGaAsP contact layer 41 is suppressed.

An example of a method for manufacturing the semiconductor optical element 500 according to Embodiment 3 will be described below.

First, the p-type InP cladding layer 14 having a carrier concentration of 1.2×10¹⁸ cm⁻³ and a layer thickness of 1.8 μm, and the active layer 12 having a layer thickness of 0.2 μm and made of an AlGaInAs based or InGaAsP based semiconductor material are sequentially crystal-grown on a main surface consisting of a (001) crystal plane of the p-type InP substrate 6 doped with Zn and having a carrier concentration of 1.2×10¹⁸ cm⁻³ by a crystal growth method such as an MOCVD or an MBE (first crystal growth step).

In the element structure described above, the active layer 12 may include a multiple quantum well structure. Optical confinement layers made of the AlGaInAs based or the InGaAsP based semiconductor material having a refractive index larger than that of the p-type InP cladding layer 14 may be provided on the upper and lower surfaces of the active layer 12. In the above description, an example of InP based semiconductor materials are given, but GaAs based semiconductor materials, GaN based semiconductor materials, or the like may be used.

After the growth of the above layers, an insulating material such as SiO₂ is deposited on the surface of the active layer 12. Examples of a method for forming the SiO₂ film include a vacuum vapor deposition method, a CVD method, and a sputtering method. After forming the SiO₂ film, the SiO₂ film is patterned into a stripe-shaped SiO₂ film having a desired width and extending in the cavity direction by photolithography and etching techniques. The stripe-shaped SiO₂ film functions as an etching mask for forming the ridge structure 13. The etching mask is not limited to the SiO₂ film, but may be a silicon nitride (SiN) film.

Using the etching mask, the ridge structure 13 with a width of 1.2 μm is formed by etching to a depth that reaches the p-type InP substrate 6 or the p-type InP cladding layer 14 (ridge structure forming step). As the etching method, dry etching is preferable, but wet etching may be used.

After the ridge structure 13 is formed, the p-type InP first buried layer 23a doped with Zn and having a carrier concentration of 1.0×10¹⁷ cm⁻³, the n-type InP second buried layer 21a doped with Si and having a carrier concentration of 7.0×10¹⁸ cm⁻³, and the p-type InP third buried layer 22a doped with Zn and having a carrier concentration of 2.0×10¹⁸ cm⁻³ are sequentially crystal-grown by MOCVD or the like so as to cover both side surfaces of the ridge structure 13, thereby forming the buried structure 24 (second crystal growth step).

Note that the constituent material of the p-type InP first buried layer 23a is not limited to InP, but may be any InP based semiconductor material. The same applies to the n-type InP second buried layer 21a and the p-type InP third buried layer 22a.

Each buried layer of the buried structure 24 may be made of a semi-insulating material such as InP doped with Ru or Fe. Further, the structure of the buried structure 24 is not limited to the above-described three-layer structure, but may be a semiconductor layer having different carrier concentration or conductivity, or a laminate obtained by combining a plurality of such semiconductor layers. After the crystal growth of the buried structure 24, the stripe-shaped SiO₂ film is removed by dry etching or the like.

Next, the n-type InP cladding layer 32 doped with Si and having a carrier concentration of 9.0×10¹⁷ cm⁻³ and a layer thickness of 2.0 μm, and the n-type InGaAsP contact layer 41 doped with Si and having a carrier concentration of 6.6×10¹⁸ cm⁻³ and a layer thickness of 0.5 μm are sequentially crystal-grown on the upper surface of the ridge structure 13 and the surfaces of the buried structures 24 by MOCVD or the like (third crystal growth step).

Note that the constituent material of the n-type InP cladding layer 32 is not limited to InP, but may be any InP based semiconductor material. The constituent material of the n-type InGaAsP contact layer 41 is not limited to InGaAsP, but may be any InGaAsP based semiconductor material.

The carrier concentration of the n-type InGaAsP contact layer 41 is set to 6.6×10¹⁸ cm⁻³ in the above-described example, but it is not limited to such a numerical value but may be any value as long as it is higher than the carrier concentration of the n-type InP cladding layer 32.

Next, a stripe-shaped resist pattern extending in the cavity direction is formed on the surface of the n-type InGaAsP contact layer 41 by photolithography and etching techniques. Using an etching mask composed of the resist pattern, etching is performed to a depth reaching the p-type InP substrate 6 or the p-type InP cladding layer 14 to form the mesa structure 53 having a width of 10 μm and including the ridge structure 13 therein (mesa structure forming step). As the etching method, wet etching is preferable, but dry etching may be used.

After the mesa structure 53 is formed, a stripe-shaped resist pattern extending in the cavity direction is formed on the upper surface of the mesa structure 53 at a position corresponding to the upper portion of the ridge structure 13 by photolithography and etching techniques. A portion corresponding to the upper portion of the ridge structure 13 is etched using an etching mask composed of the resist pattern. That is, the entire n-type InGaAsP contact layer 41 and a part of the n-type InP cladding layer 32 in the opening of the etching mask are removed by etching to form the recess 51 having a width of 1.2 μm (recess forming step).

A portion remaining on the upper surface of the ridge structure 13 in the n-type InP cladding layer 32 resulting from the formation of the recess 51 functions as the n-type InP ridge upper cladding layer 33. The layer thickness of the n-type InP ridge upper cladding layer 33 is controlled in the range of 0.3 to 0.4 μm by etching described above.

After the recess 51 is formed, an insulating film 60 made of an insulating material such as SiO₂ and having a thickness of 0.4 μm is formed so as to cover the bottom surface and the side surfaces of the recess 51, the surface of the n-type InGaAsP contact layer 41, and the both side surfaces of the mesa structure 53. Examples of a method for forming the insulating film 60 include the vacuum deposition method, the CVD method, and the sputtering method.

After the formation of the insulating film 60, a stripe-shaped resist pattern extending in the cavity direction is formed on the insulating film 60 by photolithography and etching techniques, and then the insulating film 60 is etched to expose the surface of the n-type InGaAsP contact layer 41, thereby forming the insulating film opening 61.

Next, the n-side electrode 72 is formed so as to be in contact with the n-type InGaAsP contact layer 41 through the insulating film opening 61 by using a film formation technique such as a vacuum deposition method or a sputtering method. Further, the p-side electrode 70 is formed on the rear surface of the p-type InP substrate 6 by a similar film forming method (electrode forming step).

Each of the n-side electrode 72 and the p-side electrode 70 is made of a metallic element such as Au, Pt, Zn, Ge, Ni, Ti, or a combination of two or more of these metals.

The semiconductor optical element 500 includes a front end surface and a rear end surface formed by cleavage in the optical axis direction of laser light, and thus the cavity having a length of 200 μm is formed.

Through the steps described above, the semiconductor optical element 500 according to Embodiment 2 is manufactured.

In the above description, the numerical values of the doping concentration, the layer thickness, the width, and the like of each semiconductor layer are typical examples, and are not limited to the numerical values or ranges shown in the examples.

As Modification of Embodiment 2, the recess 51 may be formed in a U-shape by wet etching using the Br based chemical solution or the like. Also in this Modification, it is possible to obtain the effect of increasing the optical confinement to the active layer 12 in the longitudinal direction by the recess 51. In addition, since the distance between the p-type InP third buried layer 22a and the recess 51 is increased, the element resistance is reduced, thus providing an effect that the operating current can be reduced.

In the semiconductor optical element 500 according to Embodiment 2, the insulating film opening 61 is formed only on one side of the upper surface of the mesa structure 53 in the lateral direction of the recess 51. However, an insulating film opening may also be formed on the other side of the upper surface of the mesa structure 53 to form a second n-side electrode. In this case, since the current can be equally supplied from the active layer 12 to the two n-side electrodes, thus providing an effect that heat generation of the semiconductor optical element is suppressed and thus power consumption is suppressed.

As another Modification of Embodiment 2, the ridge structure 13 and the recess 51 may be provided at a position shifted from the center of the mesa structure 53 in a direction perpendicular to the cavity direction. Also in this Modification, the effect of increasing the optical confinement to the active layer 12 in the longitudinal direction by the recess 51 can be obtained.

As described above, in the semiconductor optical element according to Embodiment 2, even if the semiconductor substrate and the layer structure of the opposite conductivity type to those of the semiconductor optical element according to Embodiment 1 are adopted, the recess provided in the mesa structure makes it possible to make the layer thickness of the ridge upper cladding layer provided above the active layer thinner than that of the cladding layer provided other than above the active layer. Therefore, the optical confinement to the active layer in the longitudinal direction is increased and the relaxation oscillation frequency is increased, thus providing an effect of obtaining a semiconductor optical element that enables high-speed modulation.

### Embodiment 3

FIG. 8 is a cross-sectional view in a direction perpendicular to a cavity in a semiconductor optical element 600 according to Embodiment 3. Note that an n-type InP substrate 5 is omitted in FIG. 8.

The semiconductor optical element 600 according to Embodiment 3 including: a stripe-shaped ridge structure 10 including an n-type InP cladding layer 11 (a first-conductivity-type cladding layer) and an active layer 12, which are sequentially laminated on the n-type InP substrate 5 (a first-conductivity-type semiconductor substrate); a buried structure 20 including a p-type InP first buried layer 21 (a second-conductivity-type first buried layer) and an n-type InP second buried layer 22 (a first-conductivity-type second buried layer), which are buried so as to cover both side surfaces of the stripe-shaped ridge structure 10; a p-type InP ridge upper cladding layer 31 (a second-conductivity-type ridge upper cladding layer) provided above the ridge structure 10 and having a layer thickness in a range of 0.3 to 0.4 μm; a p-type InP cladding layer 30a (a second-conductivity-type first cladding layer) and a p-type InGaAsP contact layer 40 (a second-conductivity-type contact layer) provided on a surface of the buried structure 20 on one side of the ridge structure 10; a p-type InP second cladding layer 30b (a second-conductivity-type second cladding layer) provided on the surface of the buried structure 20 on the other side of the ridge structure 10 and forming the same plane as the p-type InP ridge upper cladding layer 31; a step portion 54 formed by upper surfaces of the p-type InP second cladding layer 30b and the p-type InP ridge upper cladding layer 31 and side surfaces of the p-type InP first cladding layer 30a and the p-type InGaAsP contact layer 40; a stripe-shaped mesa structure 50 including the ridge structure 10 and having both side surfaces, the mesa structure 50 being formed by a mesa which has one side reaching the n-type InP substrate 5 from the p-type InGaAsP contact layer 40 and the other side reaching the n-type InP substrate 5 from the step portion 54; an insulating film 60 covering the step portion 54, the p-type InGaAsP contact layer 40, and the both side surfaces of the mesa structure 50; a stripe-shaped insulating film opening 61 provided in the insulating film 60 on the p-type InGaAsP contact layer 40; a p-side electrode 70 (a second-conductivity-type-side electrode) in contact with the p-type InGaAsP contact layer 40 through the insulating film opening 61; and an n-side electrode 72 (a first-conductivity-type-side electrode) provided on a rear surface of the n-type InP substrate 5.

In the semiconductor optical element 600 according to Embodiment 3, the buried structure 20 increases the optical confinement to the active layer 12 in the lateral direction, and the step portion 54 increases the optical confinement to the active layer 12 in the longitudinal direction, thus providing an effect that the relaxation oscillation frequency of the semiconductor optical element 600 is increased.

In the semiconductor optical element 600 according to Embodiment 3, the element structure is further provided with a p-side electrode 70 that contacts the p-type InGaAsP contact layer 40 through the insulating film opening 61 formed on the upper surface opposite the step portion 54 in the stripe-shaped mesa structure 50, so that the distance between the active layer 12 and the p-type InGaAsP contact layer 40 can be set to be long, thus providing an effect that the loss caused by absorption of the laser light emitted from the active layer 12 by the p-type InGaAsP contact layer 40 is suppressed.

The step portion 54 of the semiconductor optical element 600 according to Embodiment 3 can be formed, for example, as follows. First, a stripe-shaped etching mask extending in the cavity direction is formed on the upper surface of the mesa structure 50 by using an insulating material such as SiO₂. By etching and removing the p-type InP first cladding layer 30a and the p-type InGaAsP contact layer 40 from one side surface of the mesa structure 50 to the upper portion of the ridge structure 10 using an etching mask, the p-type InP ridge upper cladding layer 31 having a layer thickness in the range of 0.3 to 0.4 μm and the step portion 54 are formed. In this process, the p-type InP second cladding layer 30b, which has the same plane as the p-type InP ridge upper cladding layer 31, is also formed at the same time. Since the other configuration of the semiconductor optical element 600 is the same as that of the semiconductor optical element 100 according to Embodiment 1, the semiconductor optical element 600 can be manufactured by the same manufacturing method as that of the semiconductor optical element 100 according to Embodiment 1 described above.

As described above, in the semiconductor optical element according to Embodiment 3, the step portion provided in the mesa structure allows the thickness of the ridge upper cladding layer provided above the active layer to be thinner than that of the cladding layer provided other than above the active layer, thus providing an effect that the optical confinement to the active layer in the longitudinal direction is increased. Furthermore, the distance between the active layer and the p-type InGaAsP contact layer can be set to be long, thus providing an effect that loss caused by absorption of the laser light emitted from the active layer by the p-type InGaAsP contact layer is suppressed.

### Embodiment 4

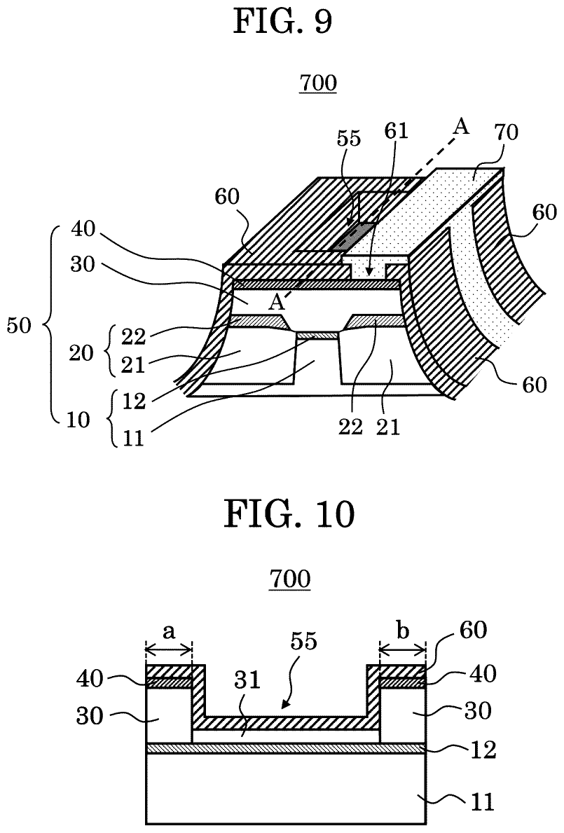

FIG. 9 is a schematic view of a semiconductor optical element 700 according to Embodiment 4, and FIG. 10 is a cross-sectional view of the A-A portion of the semiconductor optical element 700 in FIG. 9, that is, a cross-sectional view in a direction parallel to a cavity direction in a ridge structure 10 including a recess 55. Note that an n-type InP substrate 5 is omitted in FIGS. 9 and 10.

The semiconductor optical element 700 according to Embodiment 4 including: a stripe-shaped ridge structure 10 including an n-type InP cladding layer 11 (a first-conductivity-type cladding layer) and an active layer 12, which are sequentially laminated on the n-type InP substrate 5 (a first-conductivity-type semiconductor substrate); a buried structure 20 including a p-type InP first buried layer 21 (a second-conductivity-type first buried layer) and an n-type InP second buried layer 22 (a first-conductivity-type second buried layer), which are buried so as to cover both side surfaces of the stripe-shaped ridge structure 10; a p-type InP ridge upper cladding layer 31 (a second-conductivity-type ridge upper cladding layer) provided above the ridge structure 10 and formed in an area excluding both end portions in the cavity direction with a layer thickness in a range of 0.3 to 0.4 μm; a p-type InP cladding layer 30 (a second-conductivity-type cladding layer) and a p-type InGaAsP contact layer 40 (a second-conductivity-type contact layer) provided on a surface of the buried structure 20; a stripe-shaped recess 55 provided in the p-type InP cladding layer 30 and the p-type InGaAsP contact layer 40, the stripe-shaped recess 55 having a bottom surface formed of an upper surface of the p-type InP ridge upper cladding layer 31 and side surfaces formed of the p-type InP cladding layer 30 and the p-type InGaAsP contact layer 40, the stripe-shaped recess 55 being formed in a region excluding the both end portions in the cavity direction so as to correspond to a shape of the p-type InP ridge upper cladding layer 31; a stripe-shaped mesa structure 50 including the ridge structure 10 and having both side surfaces formed by a mesa extending from the p-type InGaAsP contact layer 40 to the n-type InP substrate 5; an insulating film 60 covering the bottom surface and the side surfaces of the recess 55, a surface of the p-type InGaAsP contact layer 40, and the both side surfaces of the mesa structure 50; a stripe-shaped insulating film opening 61 provided in the insulating film 60 on the p-type InGaAsP contact layer 40; a p-side electrode 70 (a second-conductivity-type-side electrode) in contact with the p-type InGaAsP contact layer 40 through the insulating film opening 61; and an n-side electrode 72 (a first-conductivity-type-side electrode) provided on a rear surface of the n-type InP substrate 5.

In the semiconductor optical element 700 according to Embodiment 4, the optical confinement to the active layer 12 in the lateral direction is increased by the buried structure 20 and the optical confinement to the active layer 12 in the longitudinal direction is increased by the presence of the recess 55, thus providing an effect that the relaxation oscillation frequency of the semiconductor optical element 700 is increased.

In the semiconductor optical element 700 according to Embodiment 4, the element structure is further provided with the p-side electrode 70 that contacts the p-type InGaAsP contact layer 40 through the insulating film opening 61 formed along the lateral direction of the recess 55 on the upper surface of the stripe-shaped mesa structure 50, so that the distance between the active layer 12 and the p-type InGaAsP contact layer 40 can be set to be long, thus providing an effect that the loss caused by absorption of the laser light emitted from the active layer 12 by the p-type InGaAsP contact layer 40 is suppressed.

In the semiconductor optical element 700 according to Embodiment 4, the recess 55 is formed in the region other than the both end portions of the semiconductor optical element 700 in the cavity direction. That is, the p-type InP ridge upper cladding layer 31 and the recess 55 are not provided in a predetermined region from both end surfaces in the cavity direction.

By adopting such the element structure, the optical confinement to the active layer 12 in the regions in the vicinity of the both end surfaces of the semiconductor optical element 700 is relatively smaller than the optical confinement in the region in which the recess 55 is provided, so that generation of end surface damage due to an increase in optical density occurring when the optical confinement is set large in the semiconductor optical element is suppressed, thus providing an effect of obtaining a highly reliable semiconductor optical element capable of performing a high output operation.

The recess 55 of the semiconductor optical element 700 according to Embodiment 4 can be manufactured, for example, as follows.

First, an etching mask is formed on the upper surface of the mesa structure 50 using an insulating material such as SiO₂. Next, a resist is patterned on the upper portion of the ridge structure 10 such that the region other than the both end portions in the cavity direction can be etched. After the resist mask is formed, the p-type InP cladding layer 30 and the p-type InGaAsP contact layer 40 are etched to form the p-type InP ridge upper cladding layer 31 having a layer thickness of 0.3 to 0.4 μm and the recess 55.

In forming the recess 55, as shown in the cross-sectional view along the cavity direction in FIG. 10, it is preferable that a distance a between the front end surface of the semiconductor optical element 700 and the recess 55, and a distance b between the rear end surface and the recess 55 are set to about 10 μm taking into account the misalignment during cleavage. However, the distance a and the distance b are not limited to such numerical values. Since the other configuration of the semiconductor optical element 700 is the same as that of the semiconductor optical element 100 according to Embodiment 1, the semiconductor optical element 700 can be manufactured by the same manufacturing method as that of the semiconductor optical element 100 according to Embodiment 1.

As described above, in the semiconductor optical element according to Embodiment 4, the recess provided in the mesa structure allows the ridge upper cladding layer provided above the active layer to be thinner than the cladding layer provided other than above the active layer, thus providing an effect that the optical confinement to the active layer in the longitudinal direction is increased and the relaxation oscillation frequency is increased. Furthermore, the optical confinement to the active layer in the regions near both end surfaces of the semiconductor optical element is made relatively smaller than the optical confinement in the region where the recess is provided, so that generation of end surface damage due to an increase in optical density is suppressed, thus providing an effect of obtaining a highly reliable semiconductor optical element capable of performing a high output operation.

Although the disclosure is described above in terms of various exemplary embodiments and implementations, it should be understood that the various features, aspects, and functionality described in one or more of the individual embodiments are not limited in their applicability to the particular embodiment with which they are described, but instead can be applied, alone or in various combinations to one or more of the embodiments of the disclosure.

It is therefore understood that numerous modifications which have not been exemplified can be devised without departing from the scope of the present disclosure. For example, at least one of the constituent components may be modified, added, or eliminated. At least one of the constituent components mentioned in at least one of the preferred embodiments may be selected and combined with the constituent components mentioned in another preferred embodiment.

### DESCRIPTION OF THE REFERENCE CHARACTERS

5 n-type InP substrate (first-conductivity-type semiconductor substrate)
6 p-type InP substrate (first-conductivity-type semiconductor substrate)
10, 13 ridge structure
11 n-type InP cladding layer (first-conductivity-type cladding layer)
12 active layer
14 p-type InP cladding layer (first-conductivity-type cladding layer)
20, 24 buried structure
21 p-type InP first buried layer (second-conductivity-type first buried layer)
21a n-type InP second buried layer (second-conductivity-type second buried layer)
22 n-type InP second buried layer (first-conductivity-type second buried layer)
22a p-type InP third buried layer (first-conductivity-type third buried layer)
23a p-type InP first buried layer (first-conductivity-type first buried layer)
30 p-type InP cladding layer (second-conductivity-type cladding layer)
30a p-type InP first cladding layer (second-conductivity-type first cladding layer)
30b p-type InP second cladding layer (second-conductivity-type second cladding layer)
31 p-type InP ridge upper cladding layer (second-conductivity-type ridge upper cladding layer)
32 n-type InP cladding layer (second-conductivity-type cladding layer)
33 n-type InP ridge upper cladding layer (second-conductivity-type ridge upper cladding layer)
40 p-type InGaAsP contact layer (second-conductivity-type contact layer)
41 n-type InGaAsP contact layer (second-conductivity-type contact layer)
50, 53 mesa structure
51, 52, 55 recess
54 step portion
60 insulating film
61, 62 insulating film opening
70, 71 p-side electrode (second-conductivity-type-side electrode)
72 n-side electrode (first-conductivity-type-side electrode)
100, 200, 300, 400, 500, 600, 700 semiconductor optical element

1. A semiconductor optical element comprising:
a first-conductivity-type semiconductor substrate;
a stripe-shaped ridge structure provided on the first-conductivity-type semiconductor substrate and including a first-conductivity-type cladding layer and an active layer;
a buried structure buried so as to cover both side surfaces of the ridge structure;
a second-conductivity-type ridge upper cladding layer provided above the ridge structure;
a second-conductivity-type cladding layer and a second-conductivity-type contact layer provided on a surface of the buried structure;
a stripe-shaped recess provided in the second-conductivity-type cladding layer and the second-conductivity-type contact layer, the stripe-shaped recess having a bottom surface formed of an upper surface of the second-conductivity-type ridge upper cladding layer, and side surfaces formed of the second-conductivity-type cladding layer and the second-conductivity-type contact layer;
a stripe-shaped mesa structure including the ridge structure and having both side surfaces formed by a mesa extending from the second-conductivity-type contact layer to the first-conductivity-type semiconductor substrate; and
an insulating film covering the bottom surface and the side surfaces of the recess, a surface of the second-conductivity-type contact layer, and the both side surfaces of the mesa structure.

2. The semiconductor optical element according to claim 1, further comprising:
a stripe-shaped insulating film opening provided in the insulating film on the second-conductivity-type contact layer; and
a second-conductivity-type-side electrode in contact with the second-conductivity-type contact layer through the insulating film opening.

3. The semiconductor optical element according to claim 2, wherein
a plurality of the insulating film openings are provided in one and the other region of the upper surface of the mesa structure that is divided by the recess, respectively.

4. The semiconductor optical element according to claim 1, wherein
a central axis of the ridge structure and a central axis of the recess are separated by a predetermined distance from a central axis of the mesa structure in a direction perpendicular to a surface of the first-conductivity-type semiconductor substrate.

5. The semiconductor optical element according to claim 1, wherein
a cross section of the recess in a direction perpendicular to a cavity has a U-shape.

6. The semiconductor optical element according to claim 1, wherein
the second-conductivity-type ridge upper cladding layer and the recess are not provided in a predetermined region from both end surfaces in a cavity direction.

7. A semiconductor optical element comprising:
a first-conductivity-type semiconductor substrate;
a stripe-shaped ridge structure provided on the first-conductivity-type semiconductor substrate and including a first-conductivity-type cladding layer and an active layer;
a buried structure buried so as to cover both side surfaces of the ridge structure;
a second-conductivity-type first cladding layer and a second-conductivity-type contact layer provided on a surface of the buried structure on one side of the ridge structure;
a second-conductivity-type ridge upper cladding layer provided above the ridge structure;
a second-conductivity-type second cladding layer provided on the surface of the buried structure on the other side of the ridge structure and forming the same plane as an upper surface of the ridge upper cladding layer;
a step portion formed by upper surfaces of the second-conductivity-type second cladding layer and the second-conductivity-type ridge upper cladding layer, and side surfaces of the second-conductivity-type first cladding layer and the second-conductivity-type contact layer;
a stripe-shaped mesa structure including the ridge structure and having both side surfaces formed by a mesa which has one side reaching the first-conductivity-type semiconductor substrate from the second-conductivity-type contact layer and the other side reaching the first-conductivity-type semiconductor substrate from the step portion;
an insulating film covering the step portion, the second-conductivity-type contact layer, and the both side surfaces of the mesa structure;
a stripe-shaped insulating film opening provided in the insulating film on the second-conductivity-type contact layer; and
a second-conductivity-type-side electrode in contact with the second-conductivity-type contact layer through the insulating film opening.

8. The semiconductor optical element according to claim 1, wherein
the second-conductivity-type ridge upper cladding layer has a layer thickness of 0.3 μm or more and 0.4 μm or less.

9. The semiconductor optical element according to claim 1, wherein
the buried structure includes at least a second-conductivity-type first buried layer and a first-conductivity-type second buried layer.

10. The semiconductor optical element according to claim 1, wherein
the buried structure includes a first-conductivity-type first buried layer, a second-conductivity-type second buried layer, and a first-conductivity-type third buried layer.

11. The semiconductor optical element according to claim 1, wherein
the first-conductivity-type is an n-type and the second-conductivity-type is a p-type.

12. The semiconductor optical element according to claim 1, wherein
the first-conductivity-type is a p-type and the second-conductivity-type is an n-type.

13. The semiconductor optical element according to claim 7, wherein
the second-conductivity-type ridge upper cladding layer has a layer thickness of 0.3 μm or more and 0.4 μm or less.

14. The semiconductor optical element according to claim 7, wherein
the buried structure includes at least a second-conductivity-type first buried layer and a first-conductivity-type second buried layer.

15. The semiconductor optical element according to claim 7, wherein
the buried structure includes a first-conductivity-type first buried layer, a second-conductivity-type second buried layer, and a first-conductivity-type third buried layer.

16. The semiconductor optical element according to claim 7, wherein
the first-conductivity-type is an n-type and the second-conductivity-type is a p-type.

17. The semiconductor optical element according to claim 7, wherein
the first-conductivity-type is a p-type and the second-conductivity-type is an n-type.
